(19) United States
(12) Patent Application Publication
(10) Pub. No.: US 2024/0353442 A1
(43) Pub. Date: Oct. 24, 2024

(54) PROBE CARD AND SEMICONDUCTOR DEVICE INSPECTION SYSTEM INCLUDING THE SAME

(71) Applicant: SAMSUNG ELECTRONICS CO., LTD., SUWON-SI (KR)

(72) Inventors: Moonil Kim, Suwon-si (KR); Kyoungmin Lee, Suwon-si (KR); Junnyeong Cho, Suwon-si (KR)

(73) Assignee: Korea University Research And Business Foundation, Seoul (KR)

(21) Appl. No.: 18/643,294

(22) Filed: Apr. 23, 2024

(30) Foreign Application Priority Data
Apr. 24, 2023 (KR) 10-2023-0053580
Jun. 27, 2023 (KR) 10-2023-0082886

(51) Int. Cl. G01R 1/04; G01R 1/067

(52) U.S. Cl. CPC G01R 1/045; G01R 1/0466; G01R 1/06722

(57) ABSTRACT

Provided are a probe card and a semiconductor device inspection system including the same. A probe card includes a socket structure including at least one socket, and a plane structure located on the socket structure. The at least one socket includes at least one RF signal pin through which a signal of a radio frequency (RF) band is transmitted, and at least one ground pin. The plane structure includes an RF plane including at least one RF signal line electrically connected to the at least one RF signal pin, and a ground plane electrically connected to the at least one ground pin, the ground plane being located between the RF plane and the socket structure.

### CROSS-REFERENCE TO RELATED APPLICATIONS

This application is based on and claims priority under 35 U.S.C. § 119 to Korean Patent Application No. 10-2023-0053580, filed on Apr. 24, 2023, and Korean Patent Application No. 10-2023-0082886, filed on Jun. 27, 2023, in the Korean Intellectual Property Office, the disclosures of which are both incorporated by reference herein in their entireties.

### BACKGROUND

The inventive concept relates to a probe card and a semiconductor device inspection system including the same, and more particularly, to a probe card having a structure that reduces or eliminates a resonance phenomenon, and a semiconductor device inspection system including the same.

After a plurality of semiconductor devices are formed on a wafer through a semiconductor device manufacturing process, an electrical characteristic test is performed on each semiconductor device. The electrical characteristic test may be performed by applying an electrical signal to the semiconductor devices on the wafer and reading an output signal corresponding to the applied electrical signal. The application and reading of the electrical signal may be performed by a probe card including a plurality of signal pins.

When a short wavelength of a radio frequency (RF) band is used during the electrical characteristics test, the signal pin of the probe card may satisfy a half-wave length of the RF band, and thus, resonance may occur. Accordingly, a probe card capable of eliminating a resonance phenomenon even when an electrical characteristic test is performed in an RF band is of interest.

### SUMMARY

The inventive concept provides a probe card configured to reduce or eliminate a resonance phenomenon by using a structure of a probe card and a semiconductor device inspection system including the same.

According to an aspect of the inventive concept, there is provided a probe card including a socket structure including at least one socket, and a plane structure located on the socket structure. The at least one socket includes at least one RF signal pin through which a signal of a radio frequency (RF) band is transmitted, and at least one ground pin. The plane structure includes an RF plane including at least one RF signal line electrically connected to the at least one RF signal pin, and a ground plane electrically connected to the at least one ground pin, the ground plane being located between the RF plane and the socket structure.

According to another aspect of the inventive concept, there is provided a probe card including a socket structure comprising a pogo pin socket, and a plane structure located on the socket structure, wherein the plane structure includes a plurality of layers, wherein the pogo pin socket comprises a first ground pin, a second ground pin, a first radio frequency (RF) signal pin, and a second RF signal pin, through which a signal of an RF band is transmitted, the plane structure comprises a first RF signal line in a first layer electrically connected to the first RF signal pin, a second RF signal line in a second layer electrically connected to the second RF signal pin, and a ground plane electrically connected to the first ground pin and the second ground pin, and the ground plane is located on a third layer closer to a lower surface of the plane structure than the first layer and the second layer, among the plurality of layers.

According to another aspect of the inventive concept, there is provided a semiconductor device inspection system including a test apparatus including a test body and a test head, and a probe card configured to be controlled by the test apparatus, wherein the probe card includes a socket including a plurality of RF signal pins through which a signal of an RF band is transmitted and a plurality of ground pins, a plurality of RF signal lines electrically connected to the plurality of RF signal pins, and a ground plane electrically connected to the plurality of ground pins, and the plurality of RF signal lines are closer to a lower surface of the test apparatus than the ground plane.

### BRIEF DESCRIPTION OF THE DRAWINGS

Embodiments will be more clearly understood from the following detailed description taken in conjunction with the accompanying drawings in which:

FIG. 1 is a diagram schematically illustrating a semiconductor device inspection system, according to an embodiment;

FIG. 2A is a cross-sectional view schematically illustrating a probe card according to an embodiment, and FIG. 2B is a plan view schematically illustrating the probe card, according to an embodiment;

FIG. 3 is a cross-sectional view schematically illustrating a probe card, according to a comparative example;

FIG. 4A is a measurement and simulation graph of a probe card during measurement of a radio frequency (RF) system, according to a comparative example, and FIG. 4B is a measurement and simulation graph of a probe card during measurement of an RF system, according to an embodiment;

FIG. 5 is a cross-sectional view schematically illustrating a probe card, according to an embodiment;

FIG. 6A is a cross-sectional view schematically illustrating a probe card, according to an embodiment, and FIG. 6B is a plan view schematically illustrating the probe card, according to an embodiment;

FIG. 7 is a simulation graph of a probe card during measurement of an RF system, according to an embodiment;

FIG. 8 is a cross-sectional view schematically illustrating a probe card, according to an embodiment;

FIG. 9 is a schematic diagram for describing a semiconductor device manufacturing system including a semiconductor module test apparatus, according to an embodiment;

FIG. 10 is a perspective view for describing a semiconductor module test apparatus, according to an embodiment;

FIG. 11 is a perspective view illustrating a socket included in the semiconductor module test apparatus of FIG. 10;

FIG. 12 is a perspective view illustrating a semiconductor module, which is a to-be-tested device insertable into a socket, according to an embodiment; and

FIG. 13 is a perspective view for describing insertion of the semiconductor module of FIG. 12 into the socket of FIG. 11.

### DETAILED DESCRIPTION OF THE EMBODIMENTS

As the present embodiments allow for various changes and numerous forms, certain embodiments will be illustrated in the drawings and described in detail in the written description. However, this is not intended to limit the present embodiments or the scope of the claims to the specific disclosed forms.

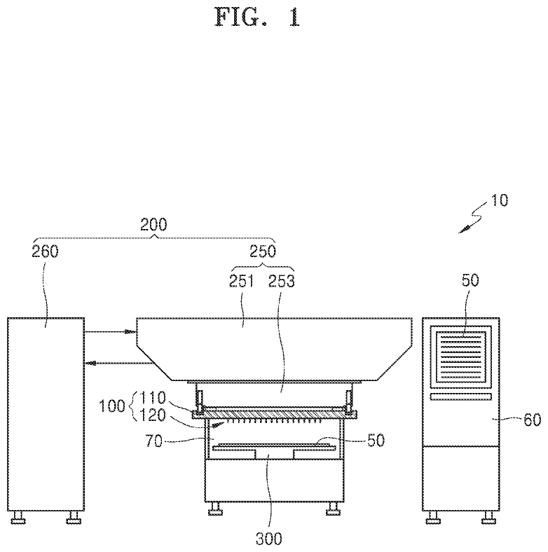

FIG. 1 is a diagram schematically illustrating a semiconductor device inspection system 10, according to an embodiment.

Referring to FIG. 1, the semiconductor device inspection system 10 may include a probe card 100, a test chamber 70, and a tester 200, where the tester may include a test head 250 and a test body 260. The probe card 100 may include probe pins 120 and a board 110 that may include a socket structure and a plane structure.

In various embodiments, the semiconductor device inspection system 10 may further include a loader chamber 60. The loader chamber 60 is a space in which wafers 50 to be tested are stored. The wafers 50 stored in the loader chamber 60 may be moved to a stage 300 of the test chamber 70 one-by-one by a moving means, so as to test the wafers 50.

In various embodiments, the test chamber 70 may provide a space for testing electrical characteristics of to-be-inspected semiconductor devices, and the stage 300 supporting the wafer 50 may be arranged in the test chamber 70. The stage 300 may support the wafer 50 and may perform a function of moving the wafer 50 up and down and/or left and right.

In various embodiments, when the wafer 50 to be tested in a test step is placed at an appropriate position, the stage 300 may move the wafer 50 upward, so that probe pins 120 of the probe card 100 and pads of each to-be-inspected device of the wafer 50 come into electrical contact with each other. When the test is finished, the stage 300 may move the wafer 50 downward away from the probe card 100 and probe pins 120.

In various embodiments, the to-be-inspected semiconductor device may be a memory device. The memory device may be a non-volatile NAND-type flash memory. For example, the memory device may include phase-change random access memory (PRAM), magnetic random access memory (MRAM), resistive random access memory (ReRAM), ferroelectric random access memory (FRAM), NOR-type flash memory, and the like. In addition, the memory device may be a volatile memory device, such as dynamic random access memory (DRAM) and static random access memory (SRAM), which loses data when power is cut off. The memory device may be a high bandwidth memory (HBM), which is a high-performance RAM interface including a stack of multiple DRAM devices. The HBM may include a base die selectively including a memory controller. The base die may be connected to dies, on which DRAM devices are formed, by through silicon vias (TSVs) and microbumps. The to-be-inspected semiconductor device may be a logic chip, a measurement device, a communication device, a digital signal processor (DSP), or a system-on-chip (SoC).

In various embodiments, the probe card 100 may be arranged so that one surface of the probe card 100 on which the probe pins 120 are disposed faces an open portion of the upper portion of the test chamber 70. In the test chamber 70, the wafer 50 may be positioned on the stage 300, so as to face the probe card 100. When the wafer 50 is positioned on the stage 300, the pads of the to-be-inspected device may be aligned with the probe pins 120 of the probe card 100 by using a flat zone or a notch of the wafer 50, where the pads can be aligned with an arrangement direction of the probe pins 120 as indicated by the notch or flat zone.

As described above, when the pads of the to-be-inspected device are aligned under the vertical direction of the probe pins 120 of the probe card 100, the stage 300 may move linearly in the vertical direction, and thus, the pads of the to-be-inspected device inside the wafer 50 may come into electrical contact with the probe pins 120 of the probe card 100.

In various embodiments, the tester 200 may provide a plurality of electrical signals to the one or more to-be-inspected semiconductor devices on a wafer 50. The tester 200 may be referred to as a test apparatus. The tester 200 may include a test head 250 and a test body 260, where the test body 260 may be electrically connected to the test head 250, so that data may be transmitted and received therebetween through wired or wireless communication.

In various embodiments, the test head 250 may include a test head board 251 and a base 253. The test head board 251 can be configured as a part constituting the body of the test head 250. The test head board 251 may have a rectangular flat plate shape (e.g., rectangular prism) and may have an inclined side surface, so that the area of the lower surface of the test head board 251 may be smaller than the area of the upper surface of the test head board 251. However, the shape of the test head board 251 is not limited thereto. For example, the test head board 251 may have a general rectangular or circular flat plate shape (e.g., disc) in which the upper surface thereof is the same as the lower surface thereof.

In various embodiments, the base 253 may be disposed on the lower surface of the test head board 251 and may have a ring shape with an empty central portion (e.g, an annulus). The probe card 100 may be coupled to the lower surface of the base 253, where the base 253 may have various structures according to the shape of the probe card 100.

In various embodiments, the test body 260 may generate the electrical signals for testing the to-be-inspected devices and may provide the electrical signals to the to-be-inspected devices on the wafer 50 through the test head 250 and the probe card 100. In addition, the test body 260 may receive output signals, which are output from the to-be-inspected devices, through the probe card 100 and the test head 250 in response to the electrical signals transmitted to the to-be-inspected devices, which may determine whether the to-be-inspected devices are defective, and/or may determine whether the probe pins 120 of the probe card 100 are defective.

In various embodiments, the semiconductor device inspection system 10 may perform at least one of a direct current (DC) test or an alternating current (AC) test on the wafer 50 to test the electrical characteristics of the to-be-inspected devices. The DC test may be a test for determining whether the devices are defective by applying a certain potential to an input pad of the wafer 50 and measuring DC characteristics, such as open/short, input current, output potential, and power supply current. In addition, the AC test may be a test for determining whether the devices are defective by applying a pulse signal to the input pad of the wafer 50 and measuring operating characteristics, such as input/output transfer delay time and start/end time of an output signal.

In various embodiments, the probe card 100 may be attached to or detached from the tester 200, where the probe card 100 may be attached to or detached from the tester 200 according to the driving of the test head 250.

In various embodiments, the probe card 100 may include a board 110 and probe pins 120. In various embodiments, the board 110 may be a printed circuit board (PCB). The board 110 may include a socket structure and a plane structure disposed on the upper surface of the socket structure and including line structures. In various embodiments, the socket structure may include a dielectric socket, and the probe pins 120 may be attached to or detached from the dielectric socket. In various embodiments, the dielectric socket may be attached to or detached from the socket structure, and the dielectric socket may include the probe pins 120.

In various embodiments, the board 110 may have a shielding structure. The shielding structure may refer to a structure in which a ground plane connected to the ground is located between the socket structure and lines through which a signal of an RF band is transmitted, among the line structures of the plane structure. The RF band may refer to electromagnetic waves having a wavelength of 0.1 mm or greater, that is, a frequency of 3 THz or less.

In various embodiments, the dielectric socket may include at least one RF signal pin through which a signal of an RF band is transmitted and at least one ground pin. The plane structure may include an RF plane including at least one RF signal line electrically connected to the at least one RF signal pin and a ground plane including at least one ground line electrically connected to the at least one ground pin. The ground plane may be located between the RF plane and the socket structure and may shield the RF plane and the dielectric socket from each other. Such a structure may be referred to as a shielding structure.

The signal of the RF signal pin may pass through the dielectric socket. However, because the signal of the RF signal pin is shielded by the ground plane between the dielectric socket and the RF plane, signal leakage may be prevented. That is, the signal of the RF signal pin may be prevented from leaking to the RF signal line. Therefore, even when the length of the RF signal pin satisfies the half-wave length of the RF band, a resonance phenomenon caused by signal leakage may be eliminated by the shielding structure. As the resonance phenomenon is reduced or eliminated, the accuracy of the electrical characteristic test of the semiconductor device using the probe card may increase.

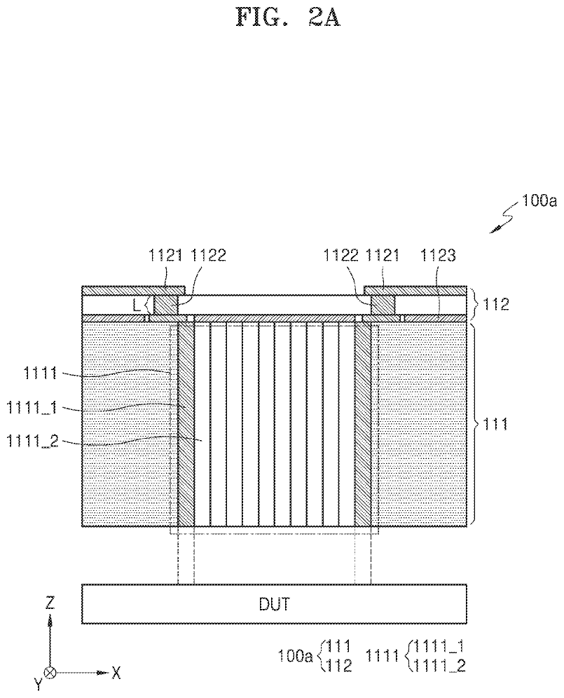

In various embodiments, the plane structure of the board 110 may include a plurality of layers. The RF plane of the plane structure may be located at a layer other than a layer that is in direct contact with the lower surface of the plane structure among the layers, and the ground plane of the plane structure may be located at a layer closer to the lower surface of the plane structure than the RF plane. In this regard, some embodiments will be described below with reference to FIGS. 2A and 2B.

Because the size of each of the to-be-inspected devices formed on the wafer 50 is very small, it is very difficult to directly connect the tester 200, which generates the electrical signal, to each of the to-be-inspected devices. Therefore, the probe card 100 may be used as an intermediate medium between the tester 200 which generates the electrical signal and the wafer 50 on which the to-be-inspected devices are formed.

In various embodiments, the tester 200 may be in physical contact with the board 110 of the probe card 100 and may be electrically connected thereto. The signal transmitted by the tester 200 may pass through the board 110 of the probe card 100 and may be transmitted to the wafer 50 through the probe pins 120.

In various embodiments, the board 110 may have a disk shape. A plurality of male or female connectors formed in the circumferential direction may be formed on the upper surface of the board 110. The probe card 100 may be connected to the test head 250 disposed thereabove by using the male or female connectors.

In various embodiments, the probe pins 120 may be bonded to one surface of the board 110, may be placed in physical contact with the to-be-inspected devices, and may transmit, to the to-be-inspected devices, the electrical signals received from the tester 200. Specifically, the probe pins 120 may be in electrical contact with the pads of the to-be-inspected devices and transmit, to the pads, at least one of the electrical signals received from the tester 200, for example, power and signals. In various embodiments, after the test process is completed, the probe pins 120 may be removed from the probe card 100.

FIG. 2A is a cross-sectional view schematically illustrating a probe card 100a according to an embodiment, and FIG. 2B is a plan view schematically illustrating the probe card 100a according to an embodiment. In various embodiments, the probe card 100a of FIGS. 2A and 2B may be an example of the probe card 100 of FIG. 1, and descriptions redundant to those of FIG. 1 may be omitted. Referring to FIGS. 2A and 2B, the probe card 100a may include a socket structure 111 and a plane structure 112.

In various embodiments, the socket structure 111 may be formed of a dielectric material, and the dielectric material may refer to an electrical insulator having a polarity within an electric field. In some embodiments, the socket structure 111 may include at least one socket 1111. Alternatively, the at least one socket 1111 may be attached to or detached from the socket structure 111.

In various embodiments, the socket 1111 may include at least one RF signal pin 1111_1 and at least one ground pin 1111_2. In various embodiments, the socket 1111 may include pins through which an electrical signal for testing electrical characteristics of a device under test (DUT), that can include a plurality of semiconductor devices, is transmitted, and the at least one RF signal pin 1111_1 and the at least one ground pin 1111_2 may be pins through which an electrical signal is transmitted to the DUT. In the present embodiment, the socket 1111 has been described as including the at least one RF signal pin 1111_1 and the at least one ground pin 1111_2, but the inventive concept is not limited thereto. For example, the socket 1111 may further include a pin through which an electrical signal for testing electrical characteristics of the DUT is transmitted. Examples of the pin may include an AC pin through which an AC signal is transmitted or a DC pin through which a DC signal is transmitted.

In various embodiments, the DUT may be a memory device. The memory device may be a non-volatile NAND-type flash memory. According to various embodiments, the memory device may include PRAM, MRAM, ReRAM, FRAM, NOR-type flash memory, and the like. In addition, the memory device may be a volatile memory device, such as DRAM and SRAM, which loses data when power is cut off. According to various embodiments, the memory device may be an HBM, which is a high-performance RAM interface including a stack of multiple DRAM devices. The HBM may include a base die selectively including a memory controller. The base die may be connected to dies, on which DRAM devices are formed, by TSVs and microbumps. According to various embodiments, the DUT may be a logic chip, a measurement device, a communication device, a DSP, or an SoC.

In various embodiments, the socket 1111 may be a pogo pin socket including a pogo-type pin using a pogo pin, but the inventive concept is not limited thereto. For example, the socket 1111 may include a rubber-type pin using pressure conductive rubber (PCR) or may include a press pin.

In various embodiments, the plane structure 112 may be located on the socket structure 111 and may include line structures, where for example, the plane structure 112 may be in direct contact with the upper surface of the socket structure 111.

In various embodiments, the plane structure 112 may include an RF plane 1121, a first via 1122, and a ground plane 1123. The RF plane 1121 is an electrical path (e.g., line) through which a signal of an RF band can be transmitted, and may include at least one RF signal line. In various embodiments, the RF plane 1121 may include a first RF signal line 1121_1 and a second RF signal line 1121_2, as shown e.g., in FIG. 2B. The first RF signal line 1121_1 and the second RF signal line 1121_2 may be electrically connected to the RF signal pins 1111_1, respectively. For example, the first RF signal line 1121_1 may be electrically connected through the first via 1122 to the at least one RF signal pin 1111_1 including a first RF signal pin 1111_11. The second RF signal line 1121_2 may be electrically connected through the first via 1122 to the at least one RF signal pin 1111_1 including a second RF signal pin 1111_12.

In various embodiments, the ground plane 1123 may include at least one ground line connected to the ground, and the at least one ground line may be electrically connected to at least one ground pin 1111_2. In various embodiments, the ground plane 1123 may be connected to the ground, and one ground plane 1123 may be electrically connected to the at least one ground pin 1111_2. For example, the ground plane 1123 may be electrically connected to a plurality of ground pins 1111_2 including a first ground pin 1111_21 and a second ground pin 1111_22. The first ground pin may be closer to a side surface of the pogo pin socket than the first RF signal pin, and the second ground pin may be closer to the side surface of the pogo pin socket than the second RF signal pin.

In various embodiments, the first via 1122 may be a conductive via. The first via 1122 and the ground plane 1123 may each include at least one conductive material selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), graphene, and an alloy metal thereof.

In various embodiments, the plane structure 112 may have a shielding structure. The shielding structure may refer to a structure in which the ground plane 1123 is located between the RF plane 1121 and the socket structure 111. In various embodiments, the ground plane 1123 may be in direct contact with the upper surface of the socket structure 111, and the first via 1122 may electrically connect the RF signal pin 1111_1 to the RF plane 1121 by passing through the ground plane 1123 on the upper surface of the socket structure 111, where the RF signal pin 1111_1 is located. The first via 1122 may be electrically insulated from the ground plane 1123.

In various embodiments, the ground plane 1123 may be electrically connected to the ground pin 1111_2 through a second via. For example, the ground plane 1123 may not be in direct contact with the upper surface of the socket structure 111, and the first via 1122 may electrically connect the RF signal pin 1111_1 to the RF plane 1121 by passing through the ground plane 1123 on the upper surface of the socket structure 111, where the RF signal pin 1111_1 is located. A vertical length L of the first via 1122 may be greater than a vertical length of the second via. The vertical length may refer to a length from the upper surface of the socket structure 111 to the lower surface of the RF plane 1121 or the lower surface of the ground plane 1123.

In various embodiments, the plane structure 112 may include a plurality of layers. For example, a layer in direct contact with the lower surface of the plane structure 112 and the upper surface of the socket structure 111 may be referred to as a lowermost layer, and a layer in direct contact with the upper surface of the plane structure 112 may be referred to as an uppermost layer. A layer between the lowermost layer and the uppermost layer may be referred to as an intermediate layer. The RF plane 1121 may be closer to the uppermost layer than the ground plane 1123. For example, the RF plane 1121 may be located on the uppermost layer, and the ground plane 1123 may be located on a layer other than the uppermost layer.

Due to the shielding structure of the plane structure 112, the signal of the RF signal pin 1111_1 may pass through the socket structure 111 formed of the dielectric material, but the signal of the RF signal pin 1111_1 is shielded by the ground plane 1123 formed of a conductive material. Accordingly, signal leakage to the RF plane 1121 may be prevented. Therefore, even when the length of the RF signal pin 1111_1 satisfies the half-wave length of the RF band, a resonance phenomenon caused by signal leakage may be reduced or eliminated by the shielding structure. When the resonance phenomenon is reduced or eliminated, the accuracy of the electrical characteristic test of the semiconductor device by using the probe card 100a may increase. The shielding structure of the plane structure 112 may be relatively easy to manufacture and may have an advantage in terms of manufacturing difficulty and manufacturing costs, compared to modifying a pin through which an electrical signal is transmitted to the socket 1111 or the DUT. In addition, because the shielding structure of the plane structure 112 may be modified according to the socket 1111, the same resonance elimination effect may be obtained for various sockets 1111.

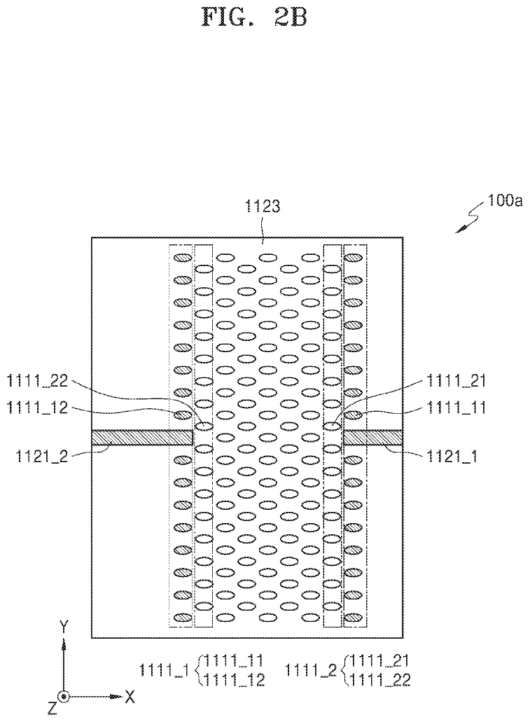

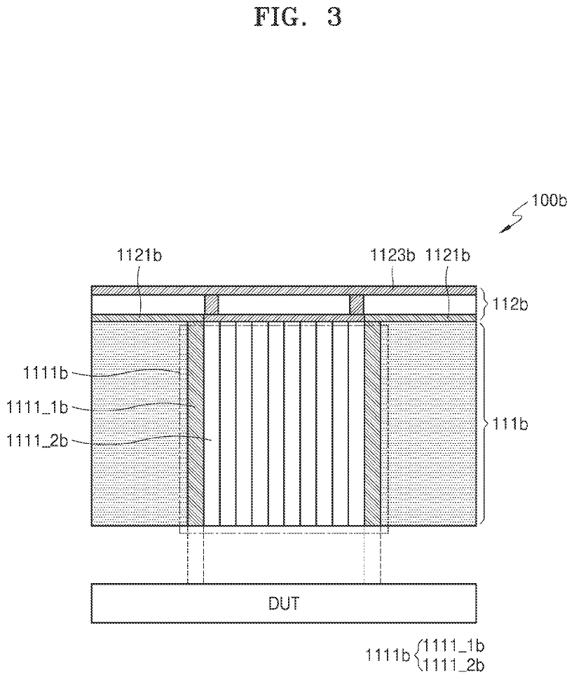

FIG. 3 is a cross-sectional view schematically illustrating a probe card 100b, according to a comparative example. FIG. 4A is a measurement and simulation graph of a probe card during measurement of an RF system, according to a comparative example, and FIG. 4B is a measurement and simulation graph of a probe card during measurement of an RF system, according to an embodiment.

Referring to FIG. 3, the probe card 100b may include a socket structure 111b and a plane structure 112b. The socket structure 111b may include at least one socket 1111b including an RF signal pin 1111_1b through which a signal of an RF band is transmitted and a ground pin 1111_2b. The socket structure 111b may be a structure formed of a dielectric material.

In various embodiments, the plane structure 112b may include an RF plane 1121b electrically connected to the RF signal pin 1111_1b and a ground plane 1123b electrically connected to the ground pin 1111_2b. The RF plane 1121b may be located between the ground plane 1123b and the socket structure 111b and may be in direct contact with or adjacent to the socket structure 111b. A signal of the RF signal pin 1111_1b may pass through the socket structure 111b formed of the dielectric material, and the signal may leak to the RF plane 1121b that is in direct contact with or adjacent to the socket structure 111b. Accordingly, coupling may occur between the RF signal pin 1111_1b and the RF plane 1121b. When the length of the RF signal pin 1111_1b satisfies the half-wave length of the RF band, resonance may occur and a dead band may exist. Coupling may refer to an interaction in which energy is transferred between two or more circuits or systems.

Referring further to FIG. 4A, a graph 400a may be a graph showing result values obtained by RF system measurement 420a and simulation 410a by using the probe card 100b of FIG. 3. In the case of an ideal probe card, in RF system measurement and simulation graphs, frequency and signal transmission may be inversely proportional to each other, where signal transmission decreases with signal frequency. When out of this relationship, resonance may occur and the corresponding frequency band may be a dead band. In the graph 400a, due to the structure in which the RF plane 1121b is located between the ground plane 1123b and the socket structure 111b, the signal of the RF signal pin 1111_1b may leak to the RF plane 1121b and a dead band may occur in a high frequency band F1, where the RF system measurement 420a is less than the simulation 410a.

On the other hand, referring to FIGS. 2 and 4B, a high frequency band F2 may be the same band as the RF band F1 of the graph 400a, and it is confirmed that a dead band is reduced in the high frequency band F2. A graph 400b may be a graph showing result values obtained by RF system measurement 410b and simulation 420b by using the probe card 100a of FIG. 2. The plane structure 112 of FIG. 2 may have a shielding structure, and the signal of the RF signal pin 1111_1 of FIG. 2 may pass through the socket structure 111 of FIG. 2 formed of a dielectric material, but the signal of the RF signal pin 1111_1 is shielded by the ground plane 1123 of the embodiment depicted in FIG. 2 formed of a conductive material, signal leakage to the RF plane 1121 of FIG. 2 may be reduced or prevented. Accordingly, a dead band may be reduced in the high frequency band F2.

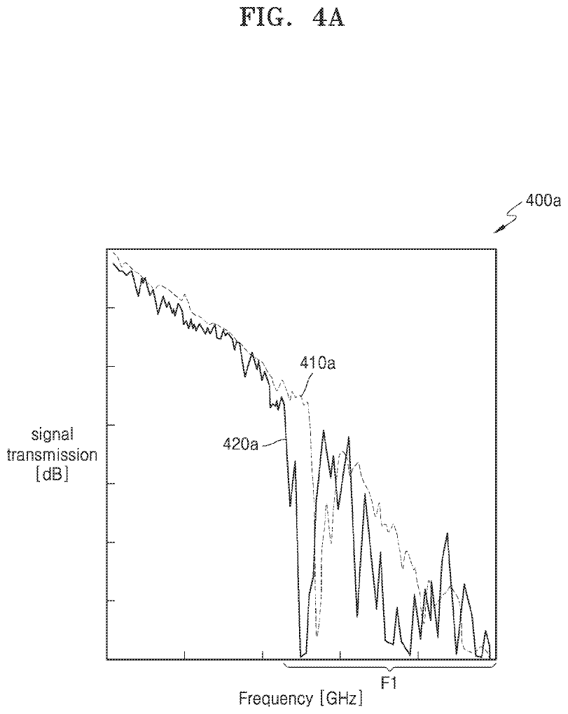

FIG. 5 is a cross-sectional view schematically illustrating a probe card 100c, according to an embodiment. In various embodiments, the probe card 100c of FIG. 5 may be an example of the probe card 100a of FIG. 2B, and descriptions redundant to those of FIGS. 2A and 2B may be omitted. Referring to FIG. 5, the probe card 100c may include a socket structure 111c and a plane structure 112c. The socket structure 111c may be the same as the socket structure 111 of FIGS. 2A and 2B.

In various embodiments, the plane structure 112c may include an RF plane 1121c, a first via 1122c, a ground plane 1123c, and an absorption plane 1124. The RF plane 1121c, the first via 1122c, and the ground plane 1123c may be the same as the RF plane 1121, the first via 1122, and the ground plane 1123 in FIGS. 2A and 2B.

In various embodiments, the absorption plane 1124 may be located between the RF plane 1121c and the ground plane 1123c and may include an absorber that absorbs electromagnetic waves. In some embodiments, the absorption plane 1124 may be in direct contact with the upper surface of the ground plane 1123c, may be in direct contact with the lower surface of the RF plane 1121c, or may not be in direct contact with either of the ground plane 1123c and the RF plane 1121c.

In various embodiments, when the ground plane 1123c is not in direct contact with the upper surface of the socket structure 111c, the absorption plane 1124 may be located between the lower surface of the ground plane 1123c and the upper surface of the socket structure 111c.

A signal of an RF signal pin 1111_1c may pass through the socket structure 111c formed of a dielectric, and the absorption plane 1124 may absorb a leakage signal. Accordingly, even when the length of the RF signal pin 1111_1c satisfies the half-wave length of the RF band, a resonance phenomenon caused by signal leakage may be reduced or eliminated by the shielding structure. When the resonance phenomenon is reduced or eliminated, the accuracy of the electrical characteristic test of the semiconductor device by using the probe card 100c may increase.

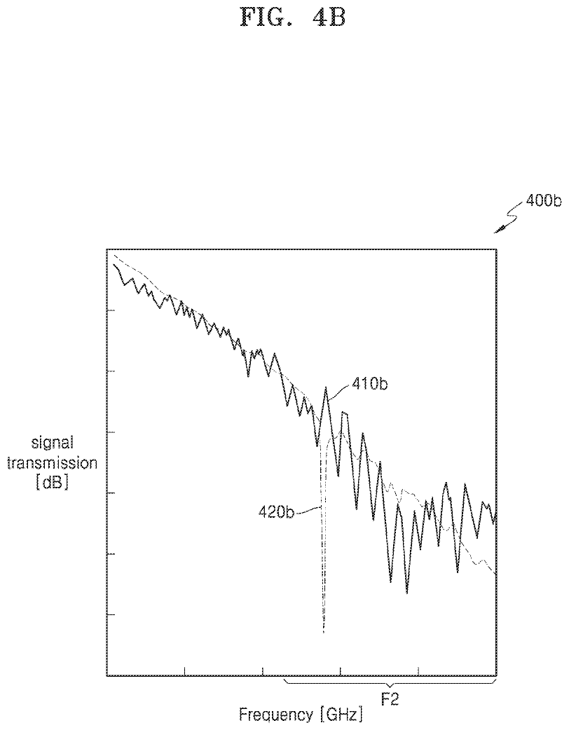

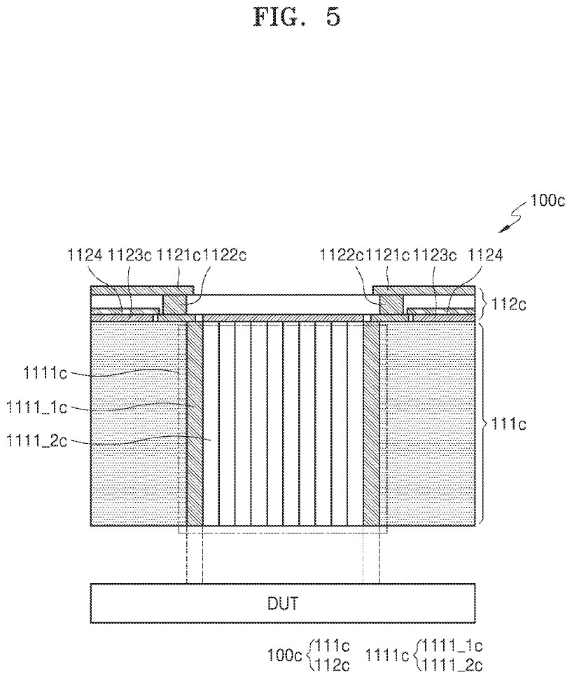

FIG. 6A is a cross-sectional view schematically illustrating a probe card 100d according to an embodiment, and FIG. 6B is a plan view schematically illustrating the probe card 100d according to an embodiment. FIG. 7 is a simulation graph of a probe card during measurement of a radio frequency system, according to an embodiment. In various embodiments, the probe card 100d of FIGS. 6A and 6B may be an example of the probe card 100a of FIGS. 2A and 2B, and descriptions redundant to those of FIGS. 1, 2A, and 2B may be omitted. Referring to FIGS. 6A and 6B, the probe card 100d may include a socket structure 111d and a plane structure 112d.

In various embodiments, the socket structure 111d may include at least one socket 1111d. The socket 1111d may include an RF signal pin 1111_1d and a ground pin 1111_2d, where the ground pin 1111_2d can be farther from the center of the socket 1111d than the RF signal pin 1111_1d. In various embodiments, the ground pin 1111_2d may be closer to the side surface of the socket 1111d than the RF signal pin 1111_1d. For example, the ground pin 1111_2d may be in direct contact with the side of the socket 1111d. The RF signal pin 1111_1d may be in direct contact with the ground pin 1111_2d.

In various embodiments, the plane structure 112d may include an RF plane 1121d, a first via 1122d, a ground plane 1123d, and a second via 1125. The RF plane 1121d may be electrically connected to the RF signal pin 1111_1d through the first via 1122d, and the ground plane 1123d may be electrically connected to the ground pin 1111_2d through the second via 1125.

In comparative examples, resonance may occur when signal polarities cross each other in a probe card, and a dead band may exist due to the resonance. A case where signal polarities cross each other may refer to a case where polarities of the signal of the ground pin and the signal of the RF signal pin configured to transmit the signal of the RF band within the probe card and polarities of the signal of the RF line connected to the RF signal pin and the signal of the ground line connected to the ground pin are opposite to each other. For example, the signal flowing through the RF signal pin may be located in a direction perpendicular leftward to the direction of the signal flowing through the ground pin. The signal flowing through the RF line may be located in a direction perpendicular rightward to the direction of the signal flowing through the ground line. Accordingly, the directions of the signals cross each other, and this may be said that the signal polarities cross each other.

On the other hand, when the ground pin 1111_2d is closer to the side surface of the socket 1111d than the RF signal pin 1111_1d, the signal polarities between the RF signal pin 1111_1d, the ground pin 1111_2d, the RF plane 1121d, and the ground plane 1123d may not cross each other. For example, when an electrical signal is input from the probe card 100d to the DUT, the signal flowing through the RF signal pin 1111_1d may be located in a direction perpendicular rightward to the direction of the signal flowing through the ground pin 1111_2d. The signal flowing through the RF plane 1121d may be located in a direction perpendicular rightward to the direction of the signal flowing through the ground plane 1123d. Accordingly, the directions of the signals may not cross each other, which may mean that the signal polarities do not cross each other. Because resonance does not occur due to crossing of signal polarities, a resonance phenomenon may be reduced or eliminated, and thus, a dead band caused by resonance may be reduced or eliminated. When the resonance phenomenon is reduced or eliminated, the accuracy of the electrical characteristic test of the semiconductor device by using the probe card 100d may increase.

Referring further to FIG. 7, a graph 700 may be a graph showing result values of RF system simulation using the probe card 100d. A high frequency band F3 may be the same band as the high frequency bands F1 and F2 in the graphs 400a and 400b of FIGS. 4A and 4B.

In various embodiments, the probe card 100d may have a shielding structure in which the ground plane 1123d is located between the socket structure 111d and the RF plane 1121d, and the ground pin 1111_2d is closer to the side surface of the socket 1111d than the RF signal pin 1111_1d. Accordingly, signal polarities may not cross each other. Therefore, it is confirmed that a dead band is reduced in the high frequency band F3, compared to the graphs 400a and 400b.

In various embodiments, the RF plane 1121d may be in direct contact with the upper surface of the plane structure 112d. As the distance between the RF signal pin 1111_1d and the RF plane 1121d increases, the leakage of the signal of the RF signal pin 1111_1d to the RF plane 1121d may be reduced. The distance between the RF signal pin 1111_1d and the RF plane 1121d may refer to the length of the first via 1122d from the upper surface of the socket structure 111d to the lower surface of the RF plane 1121d.

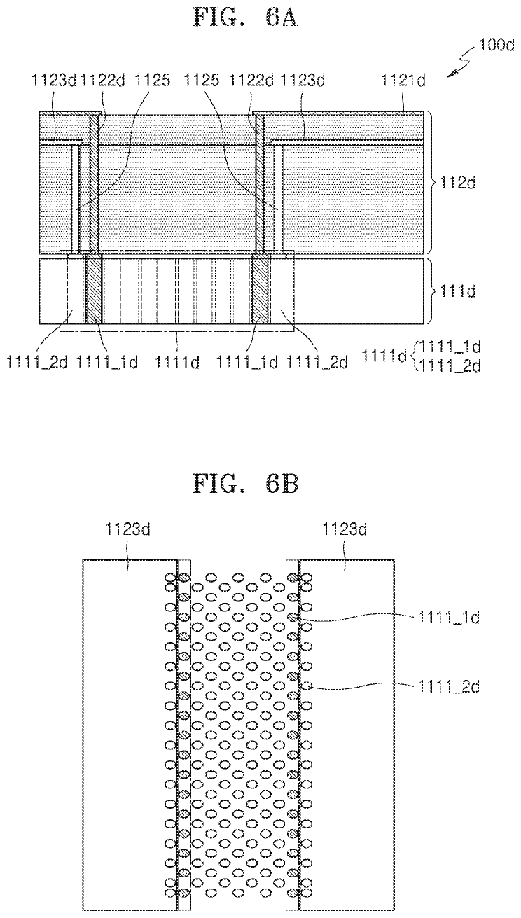

FIG. 8 is a cross-sectional view schematically illustrating a probe card 100c, according to an embodiment. In various embodiments, the probe card 100e of FIG. 8 may be an example of the probe card 100d of FIGS. 6A and 6B, and descriptions redundant to those of FIGS. 1, 6A, and 6B may be omitted. Referring to FIG. 8, the probe card 100e may include a socket structure 111e and a plane structure 112e. The socket structure 111e may be the same as the socket structure 111d of FIGS. 6A and 6B.

In various embodiments, the plane structure 112e may include an RF plane 1121e, a first via 1122e, a ground plane 1123c, a second via 1125e, and an absorption plane 1124c. The RF plane 1121e, the first via 1122e, the ground plane 1123e, and the second via 1125e may be the same as the RF plane 1121d, the first via 1122d, the ground plane 1123d, and the second via 1125 of FIGS. 6A and 6B.

In various embodiments, the absorption plane 1124e may be located between the RF plane 1121e and the ground plane 1123e, and may include an absorber that absorbs electromagnetic waves. In various embodiments, the absorption plane 1124e may be in direct contact with the upper surface of the ground plane 1123e, may be in direct contact with the lower surface of the RF plane 1121e, or may not be in direct contact with either of the ground plane 1123e and the RF plane 1121c.

In various embodiments, the socket structure 111e may include at least one socket 1111c. The socket 1111e may include an RF signal pin 1111_1e and a ground pin 1111_2e, where the ground pin 1111_2e can be farther from the center of the socket 1111e than the RF signal pin 1111_1e. In various embodiments, the ground pin 1111_2e may be closer to the side surface of the socket 1111e than the RF signal pin 1111_1e. For example, the ground pin 1111_2e may be in direct contact with the side of the socket 1111e. The RF signal pin 1111_1e may be in direct contact with the ground pin 1111_2e

In various embodiments, when the ground plane 1123e is not in direct contact with the upper surface of the socket structure 111e, the absorption plane 1124e may be located between the lower surface of the ground plane 1123e and the upper surface of the socket structure 111e.

A signal of an RF signal pin 1111_1e may pass through the socket structure 111e formed of a dielectric, but the absorption plane 1124e may absorb a leakage signal. Accordingly, even when the length of the RF signal pin 1111_1e satisfies the half-wave length of the RF band, a resonance phenomenon caused by signal leakage may be reduced or eliminated by the shielding structure. When the resonance phenomenon is reduced or eliminated, the accuracy of the electrical characteristic test of the semiconductor device by using the probe card 100e may increase.

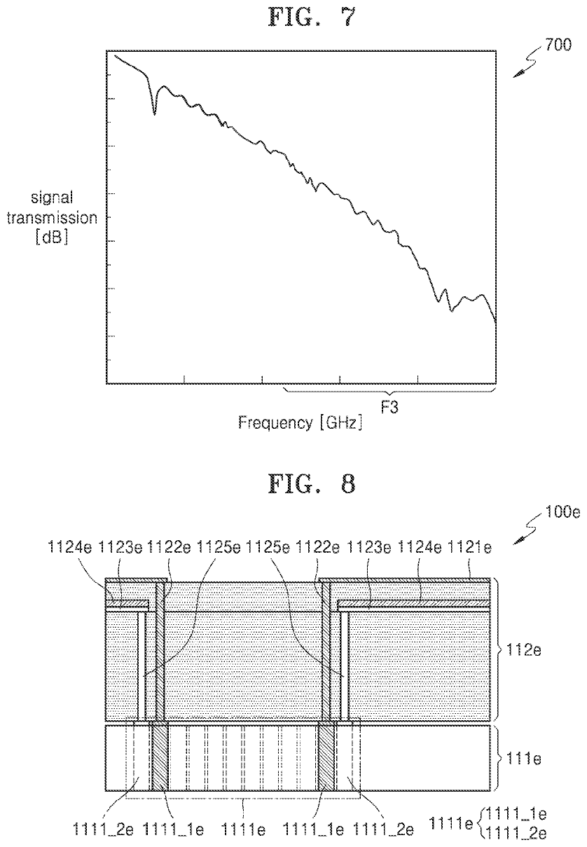

FIG. 9 is a schematic diagram for describing a semiconductor device manufacturing system 20 including a semiconductor module test apparatus 1000, according to an embodiment.

Referring to FIG. 9, the semiconductor device manufacturing system 20 may include the semiconductor module test apparatus 1000, a temperature controller 2000, a fluid supply path 3000, a control interface 4000, and a test apparatus mounting portion 5000.

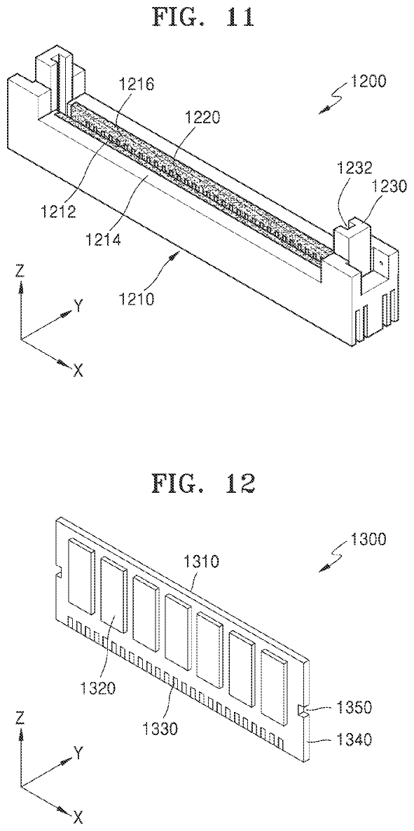

In various embodiments, the semiconductor device manufacturing system 20 may be a system for testing a semiconductor module (see e.g., 1300 of FIG. 12) including semiconductor packages (see e.g., 1320 of FIG. 12). A test by the semiconductor device manufacturing system 20 may include a DC test, a burn-in test, a monitoring burn-in test, a post-burn-in test, and/or a final test. A plurality of temperature sensors configured to measure the internal temperatures of the semiconductor packages (see e.g., 1320 of FIG. 12) and/or the semiconductor module test apparatus 1000 in real time may be provided on a test board provided in the semiconductor module test apparatus 1000. Alternatively, the semiconductor module (see e.g., 1300 of FIG. 12) tested by the semiconductor module test apparatus 1000 may include a semiconductor package with a self temperature sensor. For example, a semiconductor stack may include a resistance temperature device (RTD).

In various embodiments, the temperature controller 2000 may execute a certain temperature control program to control the fluid supply path 3000 to heat and cool the inside of the semiconductor module test apparatus 1000 and the semiconductor modules to preprogrammed target temperatures.

In various embodiments, the temperature controller 2000 may be connected to a plurality of temperature sensors and configured to compare the temperatures measured by the temperature sensors with a target temperature, and determine whether to cool or heat the inside of the semiconductor module test apparatus 1000 and the semiconductor packages. The fluid supply path 3000 may be driven to supply cooling or heating fluid FL to the semiconductor module test apparatus 1000.

In various embodiments, the control interface 4000 may include a personal computer or a central computer. The control interface 4000 may provide, to the devices to be measured, test commands for testing the operating performance of the devices according to temperature. The control interface 4000 may input a test recipe to the temperature controller 2000 and may update and modify the test recipe. In various embodiments, the control interface 4000 may provide individual commands to the temperature controller 2000 according to the test situation, based on the temperature measured by the temperature sensor.

In various embodiments, the test apparatus mounting portion 5000 may be configured to support and interconnect the respective elements of the semiconductor device manufacturing system 20. The semiconductor module test apparatus 1000 may be mounted on the test apparatus mounting portion 5000. The semiconductor test apparatus mounting portion 5000 may cover the side and bottom of the semiconductor device manufacturing system 20 in order to prevent the mounted semiconductor module test apparatus 1000 from being exposed to external foreign materials or impacts. The module test apparatus mounting portion 5000 may include a plurality of central processing unit (CPU) boards configured to control the individual semiconductor module test apparatuses 1000.

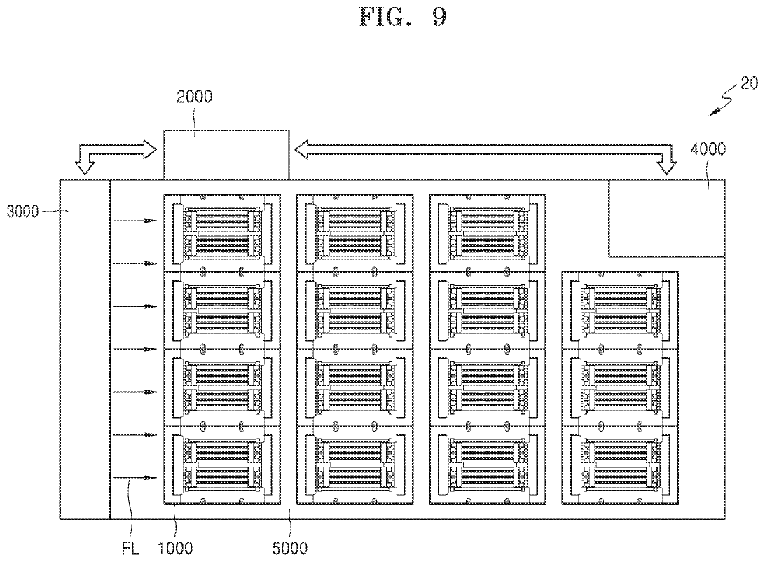

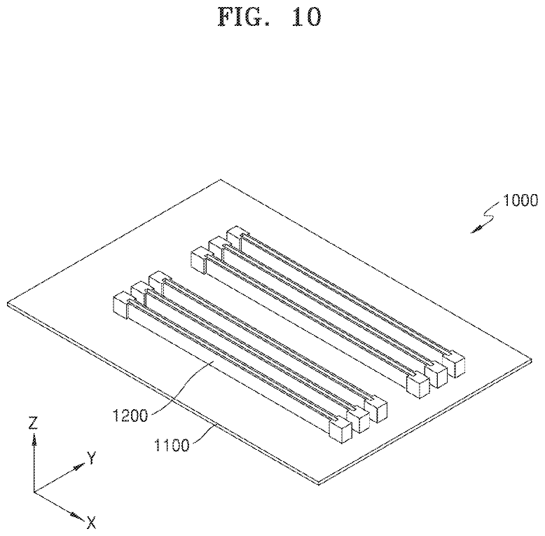

FIG. 10 is a perspective view for describing the semiconductor module test apparatus 1000 according to an embodiment. FIG. 11 is a perspective view illustrating a socket 1200 included in the semiconductor module test apparatus 1000 of FIG. 10.

Referring to FIGS. 10 and 11, the semiconductor module test apparatus 1000 may include a test board 1100 and sockets 1200. The semiconductor module test apparatus 1000 may further include a top plate disposed on the test board 1100 in order to protect the test board 1100 from external impacts and foreign materials.

Hereinafter, two directions perpendicular to each other, while being parallel to the upper surface of the test board 1100, are respectively defined as the X direction and the Y direction, and a direction substantially perpendicular to the upper surface of the test board 1100 is defined as the Z direction. In addition, when describing the respective elements before combination with the test board 1100, the directions are indicated in the same manner as described above, taking into account after combination with the test board 1100.

In various embodiments, the sockets 1200 may be spaced apart from each other by a certain distance in the Y direction of the test board 1100. The test board 1100 may be mounted with a basic circuit and elements of the semiconductor module test apparatus 1000. The test board 1100 may support the entire semiconductor module test apparatus 1000 and allow the semiconductor module test apparatus 1000 to operate stably.

In various embodiments, the semiconductor modules (see e.g., 1300 of FIG. 12), which are to-be-inspected devices, may be inserted into the sockets 1200. A plurality of socket pins 1220 corresponding to external connection terminals (see e.g., 1330 of FIG. 12) of the inserted semiconductor modules may be formed inside the sockets 1200.

FIG. 11 is a perspective view for describing the socket 1200, according to various embodiments.

Referring to FIG. 11, the socket 1200 may include a socket frame 1210, a plurality of socket pins 1220, and module coupling portions 1230.

In various embodiments, the socket frame 1210 may have a bar shape elongated in the longitudinal direction, for example, the X direction, and may include an inner body 1212 and an outer body 1214. The inner body 1212 may be formed on each side, so as to face the Y direction perpendicular to the longitudinal direction of the socket frame 1210, and may include an insulating material.

A slot 1216 extending in the longitudinal direction (e.g., X direction) may be formed in the central portion between both side surfaces of the inner body 1212. A lower end portion of a PCB (see e.g., 1310 of FIG. 12) of the semiconductor module (see 1300 of FIG. 12) may be inserted into the slot 1216. The socket pins 1220 configured to be respectively in contact with the external connection terminals (see e.g., 1330 of FIG. 12) may be arranged on both side surfaces of the slot 1216. The socket pins 1220 may be arranged in the longitudinal direction (e.g., X direction) of the socket frame 1210. The socket pins 1220 may be coupled to and supported by the inner body 1212. When the socket 1200 is installed on the test board (see e.g., 1100 of FIG. 10), the socket pins 1220 may be configured to be electrically connected to a circuit installed on the test board.

In various embodiments, the outer body 1214 may cover the exterior of the inner body 1212, where the outer body 1214 may be around the inner body 1212. The module coupling portions 1230 configured to secure the semiconductor module (see 1300 of FIG. 12) to the inner body 1212 may be arranged at both end portions of the outer body 1214 in the X direction.

In various embodiments, the socket 1200 may be configured with the shielding structure described above with reference to FIGS. 1 to 8. Due to the shielding structure, signal leakage caused by the pin which is included in the socket 1200 and through which the signal of the RF band is transmitted may be prevented. Even when the length of the pin through which the signal of the RF band satisfies the half-wave length of the RF band, the shielding structure may reduce or eliminate a resonance phenomenon caused by signal leakage. When the resonance phenomenon is reduced or eliminated, the accuracy of the electrical characteristic test of the semiconductor device by using the probe card may increase.

FIG. 12 is a perspective view illustrating a semiconductor module 1300, which is a to-be-inspected device insertable into a socket, according to various embodiments.

Referring to FIG. 12, the semiconductor module 1300 may include a PCB 1310, semiconductor packages 1320, and an external connection terminal 1330.

According to various embodiments, the semiconductor module 1300 may be a memory module. For example, the semiconductor module 1300 may include a dual inline memory module (DIMM), a small outline DIMM (SO-DIMM), an unbuffered-DIMM, or a fully buffered DIMM (FB-DIMM). However, the inventive concept is not limited thereto, and the semiconductor module 1300 may be a non-memory module.

In various embodiments, the printed circuit board (PCB) 1310 may have a rectangular plate shape. Socket fastening portions 1340 coupled to the socket 1200 may be formed at both ends of the PCB 1310 in the X direction. A hook insertion groove 1350 may be formed in the central portion of the socket fastening portion 1340 to enable more stable coupling with the socket 1200.

In various embodiments, the printed circuit board (PCB) 1310 may be a board on which the semiconductor packages 1320 are mounted. The PCB 1310 may be a PCB card, a plastic board, or semiconductor boards with other structures. The PCB 1310 may have a structure in which a plurality of metal wiring layers and a plurality of insulating layers are alternately stacked.

In various embodiments, the semiconductor packages 1320 may be non-volatile semiconductor devices (or non-volatile memory devices). In an example, the semiconductor packages 1320 may be NAND-type flash memories. In another example, the semiconductor packages 1320 may be PRAM, MRAM, ReRAM, FRAM, NOR-type flash memory, and the like. Additionally, the semiconductor packages 1320 may be volatile semiconductor devices (or volatile memory devices) such as DRAM and SRAM.

In various embodiments, the semiconductor module 1300 may further include a register. The register may be a high-speed, dedicated area that temporarily stores a very small amount of data or an intermediate result being processed. The register may include an accumulator, an arithmetic register, an instruction register, a shift register, an index register, and the like.

In various embodiments, the external connection terminals 1330 may be arranged at the lower end portion of the PCB 1310 in a line in the longitudinal direction (e.g., X direction) of the PCB 1310, where the external connection terminals 1330 may be spaced apart along the lower edge of the PCB 1310, such that the external connection terminals 1330 may align with the socket pins 1220 of the socket 1200. The external connection terminals 1330 may include a ground terminal, a power terminal, and a signal terminal. The signal terminal may include an address terminal through which an address signal is input, a command terminal through which a command signal is input, a clock terminal through which a clock signal is input, a data terminal through which data is input or output, and a power terminal through which power is provided. In some embodiments, the external connection terminal 1330 may be one of a pad, a pin, or a tab.

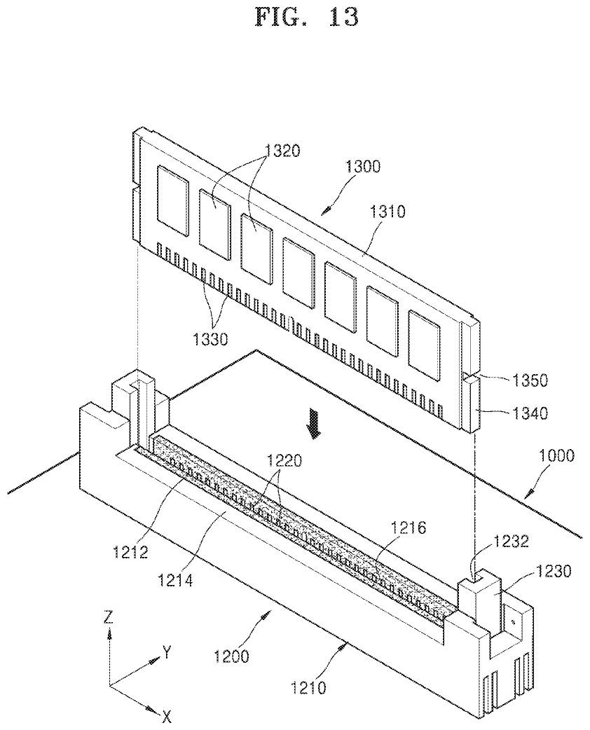

FIG. 13 is a perspective view for describing insertion of the semiconductor module 1300 of FIG. 12 into the socket 1200 of FIG. 11.

Referring to FIG. 13, the plurality of sockets 1200 may be supported on the test board 1100, and the semiconductor module 1300 may be inserted in, coupled to, and supported by a socket 1200 mounted on the test board 1100, where a plurality of semiconductor module 1300 may be accommodated by a plurality of sockets 1200. The lower end portion of the PCB 1310 of the semiconductor module 1300 may be inserted into the slot 1216 formed in the socket frame 1210 of the socket 1200. Accordingly, physical and/or electrical contact may be made between the plurality of external connection terminals 1330 arranged at the lower end portion of the PCB 1310 and the plurality of socket pins 1220 arranged on both sides of the slot 1216.

When the semiconductor modules 1300 are inserted into the plurality of sockets 1200, remnants of the external connection terminals 1330 may remain on the socket pins 1220 due to friction between the socket pins 1220 and the external connection terminals 1330. Accordingly, the contact resistance of the socket pins 1220 may increase.

In various embodiments, the test board 1100 may include an input/output (I/O) test node, a VCC test node, a resistance test input node, and a resistance test output node. The I/O test node, the VCC test node, the resistance test input node, and the resistance test output node are substantially the same as those described above with reference to FIG. 3.

In various embodiments, the socket 1200 may perform substantially the same operation as that of the probe card (see 100 of FIG. 1) described above. That is, the socket 1200 may have the shielding structure, and signal leakage caused by the pin which is included in the socket 1200 and through which the signal of the RF band is transmitted may be reduced or prevented. In addition, even when the length of the pin through which the signal of the RF band satisfies the half-wave length of the RF band, the shielding structure may reduce or eliminate a resonance phenomenon caused by signal leakage. When the resonance phenomenon is reduced or eliminated, the accuracy of the electrical characteristic test of the semiconductor device by using the probe card may increase.

While the inventive concept has been particularly shown and described with reference to embodiments thereof, it will be understood that various changes in form and details may be made therein without departing from the spirit and scope of the following claims.

What is claimed is:

1. A probe card comprising:
a socket structure comprising at least one socket; and
a plane structure located on the socket structure,
wherein the at least one socket comprises:
at least one radio frequency (RF) signal pin through which a signal of an RF band is transmitted; and
at least one ground pin, and
a plane structure comprises:
an RF plane comprising at least one RF signal line electrically connected to the at least one RF signal pin; and
a ground plane electrically connected to the at least one ground pin, the ground plane being located between the RF plane and the socket structure.

2. The probe card of claim 1, wherein the ground plane is located closer to a lower surface of the plane structure than the RF plane, and comprises a conductive material to shield the signal of the at least one RF signal pin.

3. The probe card of claim 1, wherein the plane structure further comprises an absorption plane located between the RF plane and the ground plane that absorbs a leakage signal.

4. The probe card of claim 1, wherein the plane structure further comprises at least one first via connecting the at least one RF signal pin to the at least one RF signal line, and
the ground plane is in direct contact with the socket structure.

5. The probe card of claim 2, wherein the plane structure comprises:
at least one first via connecting the at least one RF signal pin to the at least one RF signal line; and
at least one second via connecting the at least one ground pin to the ground plane, and
a vertical length of the at least one first via is greater than a vertical length of the at least one second via.

6. The probe card of claim 1, wherein the at least one ground pin is located closer to a side surface of the at least one socket than the at least one RF signal pin.

7. The probe card of claim 6, wherein the at least one ground pin is in direct contact with the at least one RF signal pin.

8. The probe card of claim 6, wherein the at least one ground pin is in direct contact with the side surface of the at least one socket.

9. The probe card of claim 6, wherein the plane structure further comprises:
at least one first via connecting the at least one RF signal pin to the at least one RF signal line; and
at least one second via connecting the at least one ground pin to the at least one ground plane.

10. The probe card of claim 9, wherein the RF plane is in direct contact with an upper surface of the plane structure.

11. The probe card of claim 6, wherein the plane structure further comprises an absorption plane located between the RF plane and the ground plane that absorbs a leakage signal.

12. A probe card comprising:
a socket structure comprising a pogo pin socket; and
a plane structure located on the socket structure, wherein the plane structure includes a plurality of layers,
wherein the pogo pin socket comprises a first ground pin, a second ground pin, a first radio frequency (RF) signal pin, and a second RF signal pin, through which a signal of an RF band is transmitted,
the plane structure comprises a first RF signal line in a first layer electrically connected to the first RF signal pin, a second RF signal line in a second layer electrically connected to the second RF signal pin, and a ground plane electrically connected to the first ground pin and the second ground pin, and
the ground plane is located on a third layer closer to a lower surface of the plane structure than the first layer and the second layer, among the plurality of layers.

13. The probe card of claim 12, wherein the third layer is in direct contact with the socket structure.

14. The probe card of claim 12, wherein the plane structure further comprises an absorption plane in contact with an upper surface of the ground plane that absorbs a leakage signal.

15. The probe card of claim 12, wherein the first ground pin is closer to a side surface of the pogo pin socket than the first RF signal pin, and
the second ground pin is closer to the side surface of the pogo pin socket than the second RF signal pin.

16. The probe card of claim 15, wherein the first ground pin and the second ground pin are in direct contact with the side surface of the pogo pin socket,
the first RF signal pin is in direct contact with the first ground pin, and
the second RF signal pin is in direct contact with the second ground pin.

17. The probe card of claim 15, wherein the first layer and the second layer are layers in direct contact with an upper surface of the plane structure.

18. A semiconductor device inspection system comprising:
a test apparatus comprising a test body and a test head; and
a probe card configured to be controlled by the test apparatus,
wherein the probe card comprises:
a socket comprising a plurality of radio frequency (RF) signal pins through which a signal of an RF band is transmitted and a plurality of ground pins;
a plurality of RF signal lines electrically connected to the plurality of RF signal pins; and
a ground plane electrically connected to the plurality of ground pins, and
the plurality of RF signal lines are closer to a lower surface of the test apparatus than the ground plane.

19. The semiconductor device inspection system of claim 18, wherein the plurality of ground pins are in direct contact with a side surface of the socket, and
the plurality of RF signal pins are in direct contact with the plurality of ground pins.

20. The semiconductor device inspection system of claim 18, further comprising an absorption plane located between the plurality of RF signal lines and the ground plane that absorbs a leakage signal.
